(19) United States
(12) Patent Application Publication
(10) Pub. No.: US 2013/0002164 A1
(43) Pub. Date: Jan. 3, 2013

(54) LED LIGHT FIXTURE

(75) Inventors: Gregory Galluccio, Hauppauge, NY (US); Francisco Schapira, Valley Stream, NY (US); Ruel Sarino, Port Washington, NY (US); Carlos Salazar, North Babylon, NY (US)

(73) Assignee: LEVITON MANUFACTURING COMPANY, INC., Melville, NY (US)

(21) Appl. No.: 13/171,871

(22) Filed: Jun. 29, 2011

(51) Int. Cl. H05B 37/02; H05K 13/00; F21S 4/00

(52) U.S. Cl. 315/294; 362/249.02; 29/401.1

(57) ABSTRACT

Light emitting diode (LED) light fixtures and methods of manufacturing LED light fixtures are provided. In one embodiment, an LED light fixture comprises a housing having a back surface, a first end portion, and a second end portion. The LED light fixture further comprises a support strip attached to the back surface of the housing adjacent to the first end portion. The support strip has at least one lamp holder configured to physically support a first end of an LED lamp. Also, the LED light fixture includes a power supply strip attached to the back surface of the housing adjacent to the second end portion. The power supply strip has at least one receptacle configured to physically support a second end of the LED lamp. The at least one receptacle is further configured to provide electrical power to the LED lamp.

### TECHNICAL FIELD

The present disclosure generally relates to light fixtures, and more particularly relates to light emitting diode (LED) light fixtures and methods of manufacturing LED light fixtures.

### BACKGROUND

Fluorescent lamp holders are typically installed in an enclosure or fixture housing with a ballast and associated wiring. The manufacturer will generally assemble the lamp holders to the sheet metal fixture, attach the ballast to the fixture, and run wires between the ballast and lamp holders. This process can be labor intensive and may lead to wiring errors and an unappealing installation.

FIG. 11 is a top view of a conventional fluorescent light fixture 250. The fluorescent light fixture 250 may include an enclosure 252, which may be a fixture housing. Surface 254 of the enclosure 252 may be a reflector. The surface 254 may have breaks in slope 256 to direct light in selected directions. The fluorescent light fixture 250 may include lamp holders 258, 260, and 262. The lamp holders 258, 260, and 262 may each hold one end of a tube-type fluorescent lamp. The other end of each lamp may be held by lamp holders 264, 266, and 268, respectively. Arrows A, B, and C show where fluorescent tubes would be placed between corresponding lamp holders. The lamp holders 258, 260, and 262 are connected to a first ballast 270 and lamp holders 264, 266, and 268 are connected to a second ballast 272. Ballasts 270 and 272 are fixed directly to enclosure 252.

FIG. 12 is a front view of a conventional fluorescent lamp holder 280. The conventional fluorescent lamp holder 280 may represent any of the lamp holders 258, 260, 262, 264, 266, or 268 and may include a view of lamp holder 260 indicated by the arrows shown in FIG. 11. As illustrated, the lamp holder 280 includes a base 282, body 284, lamp pin guide 286, and pin slot 288. Paired contact pins from a fluorescent lamp may be inserted into pin slot 288 until the pins occupy positions 290 and 292. The pins may then be rotated in directions A and R, along pin guide 286, about rotational axis X until the pins contact power terminals 294 and 296 (shown in broken lines) inside the body 284 of the fluorescent lamp holder 280.

Technology currently exists for replacing standard linear fluorescent lamps with tubular shaped LED lamps that have similar form, fit, and function to the linear fluorescent lamps. These tubular LED lamps suffer from certain common performance and safety issues. Generally, the light output of the LED tubes is substandard as compared to the linear fluorescent tubes due to the constraints on the shape of the tubes. The longevity of some of these LED lights is often compromised because the driver circuitry contained in the tube creates the need for additional heat sinking. If either one of the LED array or the driver circuitry fails, the entire LED tube, which includes both the LED array and driver circuitry, must be replaced. In addition, LED retrofit/replacement tubes often use the existing linear fluorescent sockets as connection means, resulting in possible safety hazards. Some safety hazards include but are not limited to: lamps falling out of fixtures due to the increased weight of LED tubes, improperly wired sockets resulting in short circuits, customer replacement of LED tubes with standard linear fluorescent tubes after the fixture has been rewired to accept only LED tubes, and other issues.

It would be helpful to develop a system to mitigate some of the problems with retrofitted fluorescent light fixtures.

### SUMMARY

The present disclosure describes various implementations of LED light fixtures and systems for modifying a fluorescent light fixture into a fixture that is able to illuminate LED lamps.

According to one aspect of the present disclosure, an LED light fixture includes a housing having a back surface, a first end portion, and a second end portion. The LED light fixture further comprises a support strip attached to the back surface of the housing adjacent to the first end portion. The support strip includes at least one lamp holder configured to physically support a first end of an LED lamp. Also, the LED light fixture includes a power supply strip attached to the back surface of the housing adjacent to the second end portion. The power supply strip includes at least one receptacle configured to physically support a second end of the LED lamp. The at least one receptacle is further configured to provide electrical power to the LED lamp.

In another aspect, a power supply strip of a light emitting diode (LED) light fixture includes at least one receptacle configured to engage an electrical end of at least one LED lamp; and a drive circuit configured to provide electrical power to the at least one LED lamp through the at least one receptacle; wherein each of the at least one receptacle includes electrical contacts configured to supply the electrical power from the drive circuit to the electrical end of the at least one LED lamp.

In yet another aspect, the at least one receptacle is laterally movable within an aperture of the power supply strip.

In a further aspect of the present disclosure, a method of manufacturing a light emitting diode (LED) light fixture is provided. The method includes providing a fluorescent light fixture having a first end and a second end, each of the first and second ends including one or more fluorescent tube lamp holders and a ballast; removing the fluorescent tube lamp holders and ballasts; mounting a support strip at the first end of the fluorescent light fixture, the support strip comprising at least one lamp holder configured to support a first end of at least one LED lamp; and mounting a power supply strip at the second end of the fluorescent light fixture, the power supply strip configured to support a second end of the at least one LED lamp and provide power to the at least one LED lamp.

### BRIEF DESCRIPTION OF THE DRAWINGS

The features illustrated in the following figures are intended to emphasize the general principles of the present disclosure and are not necessarily drawn to scale. Consistent reference characters are used throughout the figures to designate corresponding features.

FIGS. 1A-1C are diagrams illustrating different views of a light emitting diode (LED) lamp, according to various implementations of the present disclosure.

FIGS. 2A-2B are diagrams illustrating different views of an LED light fixture, according to various implementations of the present disclosure.

FIGS. 3A-3C are diagrams illustrating different views of a first lamp holder, according to various implementations of the present disclosure.

FIG. 4 is a diagram illustrating a perspective view of a second lamp holder, according to various implementations of the present disclosure.

FIGS. 5A-5E are diagrams illustrating different views of a third lamp holder, according to various implementations of the present disclosure.

FIGS. 6A-6E are diagrams illustrating different views of a first power supply strip, according to various implementations of the present disclosure.

FIGS. 7A-7E are diagrams illustrating different views of a second power supply strip, according to various implementations of the present disclosure.

FIGS. 8A-8C are diagrams illustrating different views of a third power supply strip, according to various implementations of the present disclosure.

FIGS. 9A-9C are diagrams illustrating different views of a fourth power supply strip, according to various implementations of the present disclosure.

FIG. 10 is a diagram illustrating a perspective view of a fourth lamp holder, according to various implementations of the present disclosure.

FIG. 11 is a diagram illustrating a top view of a conventional fluorescent light fixture.

FIG. 12 is a diagram illustrating a front view of a conventional fluorescent lamp holder.

### DETAILED DESCRIPTION

The present disclosure describes light emitting diode (LED) lamps, LED light fixtures, lamp holders, support strips, power supply strips, and systems for modifying standard fluorescent light fixtures to accommodate LED lamps. According to some embodiments, the LED lamps and power supply strips may each contain distinct lighting features to allow the components to be separately replaceable. In this way, the cost to replace defective parts may be reduced since only the parts that are no longer functional are replaced.

In some embodiments, the LED lamps may be installed into an enclosure or fixture housing designed to fit in a standard ceiling grid or other similar ceiling-mounted down-lighting fixture. The LED lamps are able to provide LED light in a pattern, color, and intensity similar to or superior to that of a standard linear fluorescent fixture of the same size. As disclosed herein, the LED lamps include LED lighting panels that are illuminated by LED driver circuits located in the power supply strips. If one or the other of the LED lamps or LED driver circuits becomes inoperative, the non-functioning part can be replaced without the need to replace the part that remains operational.

The LED lamps, according to various implementations disclosed herein, help to mitigate some of the problems with retrofitted fluorescent light fixtures. For example, some embodiments herein comprise driver circuitry that is contained in a module separate from the LED light arrays and is therefore replaceable and does not contribute heat to the light arrays. The LED light arrays can be manufactured to take on any shape that fits in the existing fixture space, and are not restricted to tubular shapes emulating T8 or T5 fluorescent lamps. This allows a lighting designer to create a better overall light output (compared to existing LED tubes) using existing fixtures. In some embodiments, the fixture wiring (not including supply wiring) for supplying power to the driver circuits may be contained within the power supply strips, resulting in fast and easy installation and/or replacement with little possibility of wiring error. For holding the weight of the LED lamps, lamp holders are positioned at each end of the LED lamps. In some embodiments, the lamp holders may be incorporated into the power supply strips. The lamp holders provide sufficient support to reduce the possibility of LED lamps falling out due to vibration or other unintentional disturbance. In some embodiments, the lamp holders may be designed in a way such that a standard fluorescent lamp will not be able to fit into the lamp holders.

It should be recognized in the present disclosure that certain relative terms, such as “top,” “bottom,” “left,” and “right” are used to refer to the orientation of the objects as shown in the drawings. However, the orientation of certain objects as suggested by the terminology may differ from the actual orientation when the light fixtures are mounted. For example, a light fixture may be mounted on a horizontal ceiling, a slanted ceiling, a vertical wall, or on other surfaces having various orientations. In the case of a downward directed light fixture mounted to a horizontal ceiling, a top section of an object as shown may actually be directed downward when installed in the fixture.

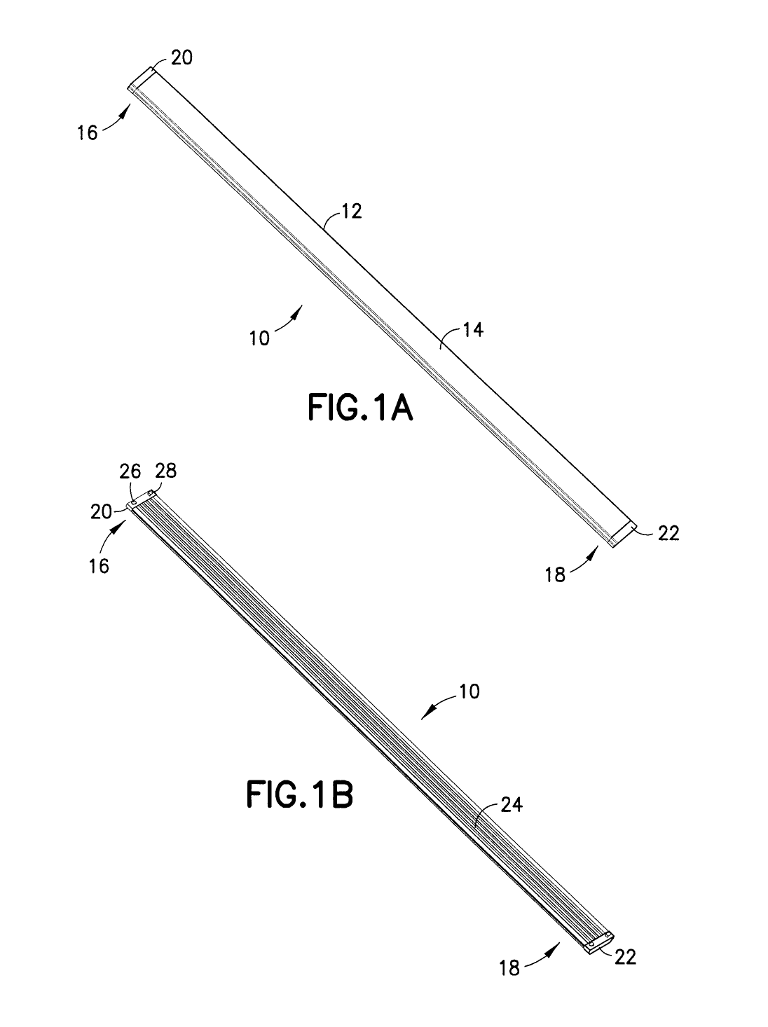

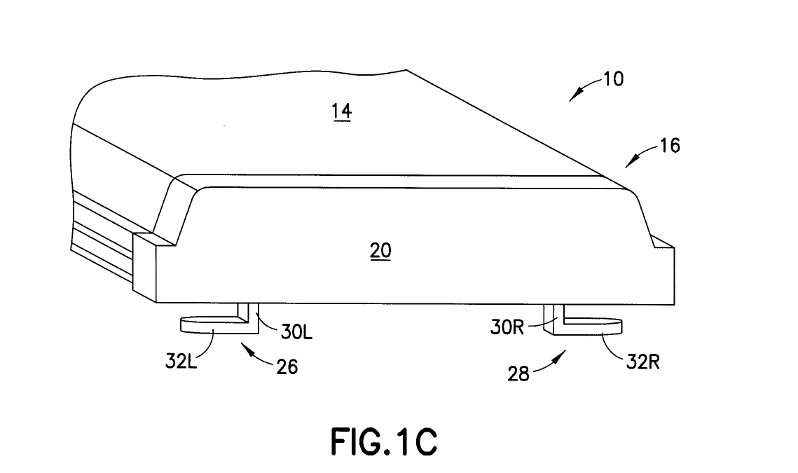

FIGS. 1A-1C are diagrams that show a first embodiment of an LED lamp 10. In this embodiment, the LED lamp 10 includes an elongated housing 12 having a top surface 14, a first end 16, and a second end 18. The housing 12 may include a cover that contains transparent or translucent material and may be configured to enclose a number of LED elements and to diffuse the light emitted from the LED elements. It is to be appreciated that the LED elements may be configured as at least one array of LED elements. In another embodiment, the LED elements may be uncovered. In some embodiments, the top surface 14 may be substantially flat. The first end 16 of the LED lamp module 10 includes a first end cap 20 and the second end 18 includes a second end cap 22. As shown in FIG. 1B, the LED lamp module 10 also includes a bottom surface 24, which in some embodiments may be substantially flat. The first end cap 20 may include a left tab 26 and a right tab 28 extending beyond the bottom surface 24. In some embodiments, the second end cap 22 may also include tabs similar to the left tab 26 and right tab 28.

The first end 16 of the LED lamp 10 is shown in FIG. 1C. The left tab 26 includes a leg 30L and a foot 32L, and the right tab 28 includes leg 30R and foot 32R. The foot 32L of the left tab 26 extends from the end of the leg 30L toward a side of the LED lamp 10 nearest to tab 26 (i.e., the left side as shown). The foot 32R of the right tab 28 extends from the end of the leg 30R toward a side of the LED lamp 10 nearest to tab 28 (i.e., the right side as shown). The tabs 26 and 28 may be used to engage with a support structure, e.g., a lamp holder, a support strip, a power supply strip, etc., as described in more detail below. In one embodiment, the tabs 26 and 28 will be formed from non-conductive material and will be employed primarily for support. In another embodiment, the tabs 26 and 28 will be formed from conductive material and will provide electrical power to the LED lamp 10 when coupled to a lamp holder containing the appropriate circuitry.

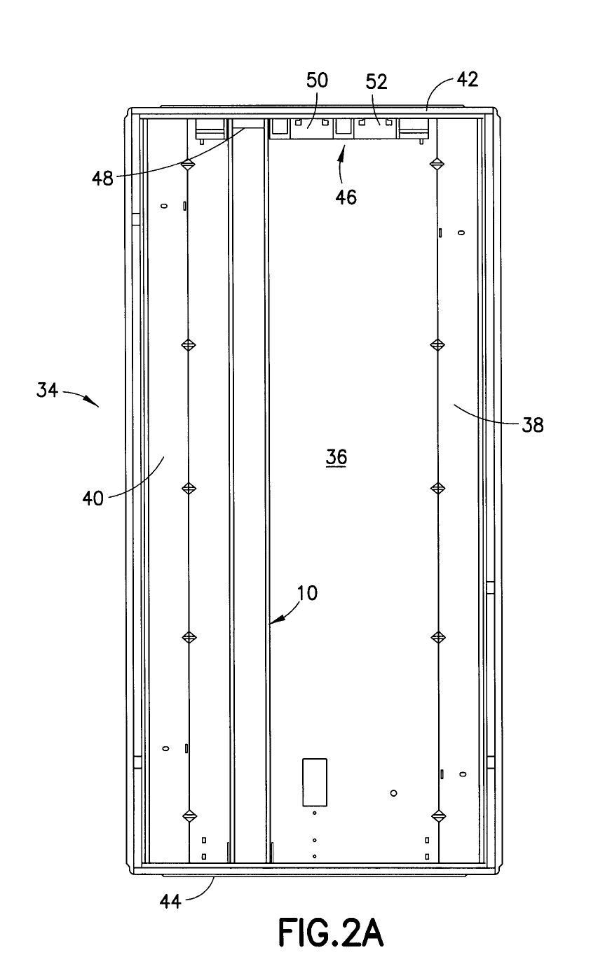

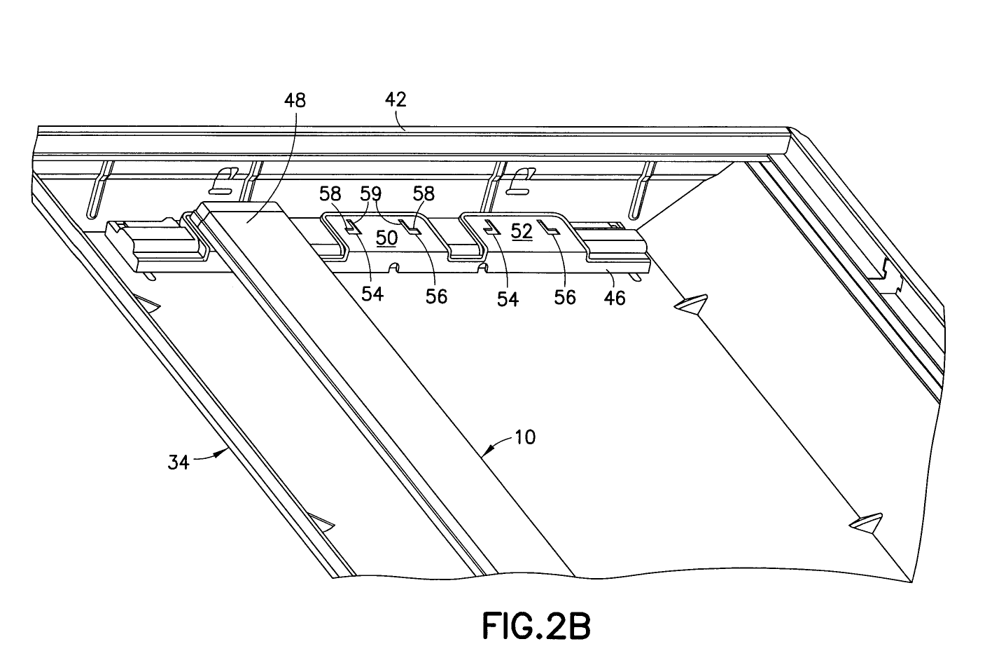

FIGS. 2A-2B are diagrams illustrating an embodiment of an LED light fixture 34, which may be configured to support the LED lamp 10 of FIG. 1. In this embodiment, the LED light fixture 34 comprises a housing that may be similar to a conventional housing of a fluorescent light fixture. According to some implementations, the LED light fixture 34 may be manufactured from new parts and may be designed to resemble a conventional fluorescent light fixture, yet accept LED lamps.

However, according to other implementations, the LED light fixture 34 may be constructed from a conventional fluorescent light fixture that has been modified for illuminating LED lamps, including but not limited to LED lamp 10, instead of fluorescent lamps. In this respect, the light fixture 34 may be a retrofitted fluorescent light fixture. When retrofitted, the ballasts of the fixture are unnecessary and may be removed. Also, the conventional lamp holders may be replaced with lamp holders that are configured to accommodate LED lamps.

As illustrated, the housing of the LED light fixture 34 includes a back surface or plate 36, first side plate 38, second side plate 40, a first end plate 42 disposed at a first end portion, and a second end plate 44 disposed at a second end portion. The plates 36-44 may be metal or another suitable material and may be connected together by any means now known or hereafter developed, including for example by welding or other connection techniques. The LED light fixture 34 may have any suitable size and shape. Also, the LED light fixture 34 may be configured to provide structural support for holding one or more LED lamps. The light fixture 34 may also be configured with electrical contacts for providing electricity to a properly mounted LED lamp.

As shown, the LED light fixture 34 may include a support strip 46 that may be affixed to the first end plate 42 and/or the back plate 36 at one end of the LED light fixture 34. The support strip 46 in this embodiment includes a first lamp holder 48 (the view of which is blocked by the LED lamp module 10), a second lamp holder 50, and a third lamp holder 52. The support strip 46 may be configured to physically support a first end of the LED lamp without providing electricity.

The light fixture 34 also includes a corresponding lamp holder or lamp holders disposed on a support strip mounted near or on the second end plate 44 at the end opposite from the first end plate 42. The corresponding lamp holder or lamp holders may be similar to lamp holders 48, 50, and 52 of support strip 46 or may comprise a different design for holding the other end of the LED lamp 10. The corresponding lamp holder or lamp holders may differ from the lamp holders 48, 50, and 52 in that electrical power may be applied to the LED lamp 10 via the lamp holders. It is to be appreciated that when lamp holders similar to lamp holders 48, 50, and 52 are provided at both the first end 42 and second end 44 of the fixture 34, power to the LED lamp 10 will be provided through other means, e.g., a wired connection to the LED lamp 10. The support strip 46 and corresponding support strip or power supply strip on the opposite end of the light fixture 34 include the same number of lamp holders to support a certain number of LED lamps 10. According to various embodiments, the support strip 46 and corresponding support strip may each have any suitable number of lamp holders for supporting any number of lamps.

The lamp holders 48, 50, and 52 may have any suitable width to accommodate the width of the LED lamps. In some embodiments, the support strip 46 may include one lamp holder having a width of about three times the width of the lamp holders shown in FIG. 2A. In this case, the lamp holders may support an LED lamp having a width about three times the width of the LED lamp 10 as shown.

As shown in FIG. 2B, each lamp holder 48, 50, and 52 includes a left aperture 54 and a right aperture 56. The apertures 54, 56 may have openings large enough to allow the tabs 26 and 28 of the LED lamp 10 to be inserted through the openings. In this example, the apertures 54, 56 may receive the feet 32 of the tabs 26, 28 through the rectangular portions 58 that have their long sides substantially parallel to the end plates 42, 44. The other portions of the apertures 54, 56 include slits 59 that accommodate the width of the legs 30 of the tabs 26, 28. To engage the tabs 26, 28 with the support strip 46, the feet 32 are inserted through the rectangular portions 58 of the apertures 54, 56 until the feet 32 are below the bottom surface of a plate in which the apertures 54, 56 are formed. Then, the LED lamp 10 is slid in a longitudinal direction with the legs 30 extending into the slits 59. In this embodiment, the LED lamp 10 is slid in a direction toward the first end plate 42. In other embodiments, the slits 59 may be arranged in the opposite direction with respect to the rectangular portions 58, such that the tabs 26, 28 of the LED lamp 10 are engaged with the lamp holders when the LED lamp 10 is slid away from the first end plate 42.

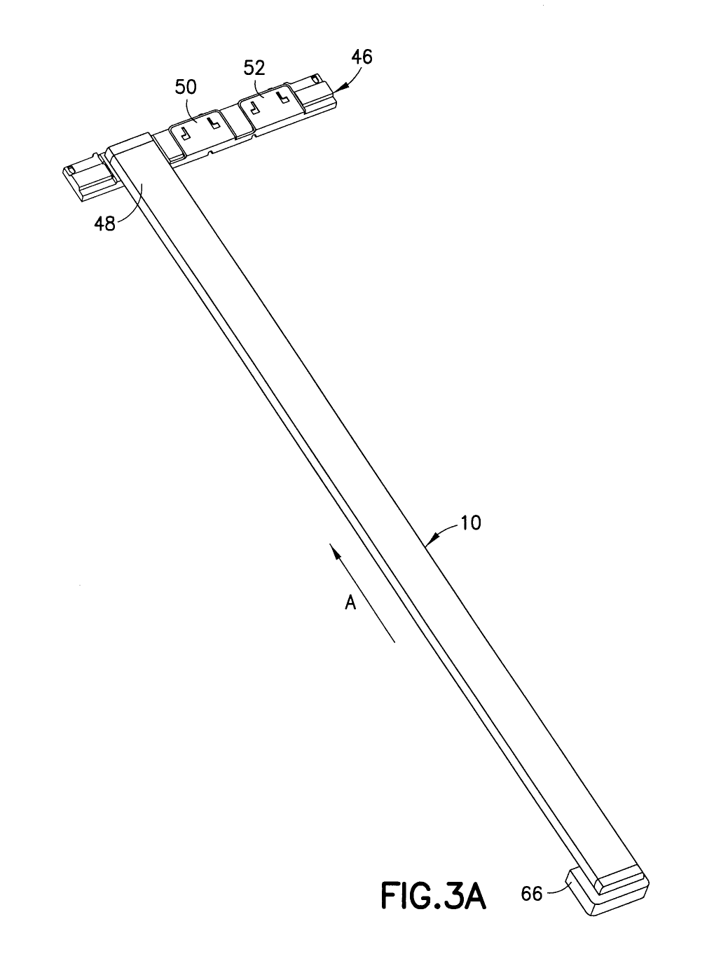

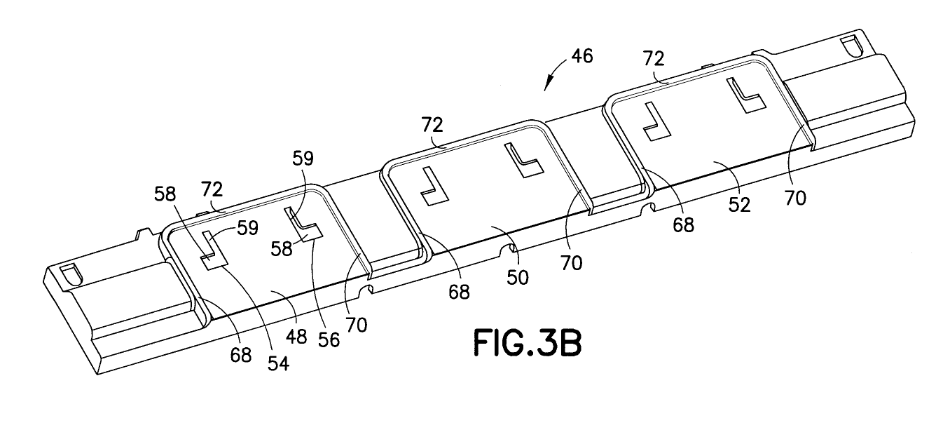

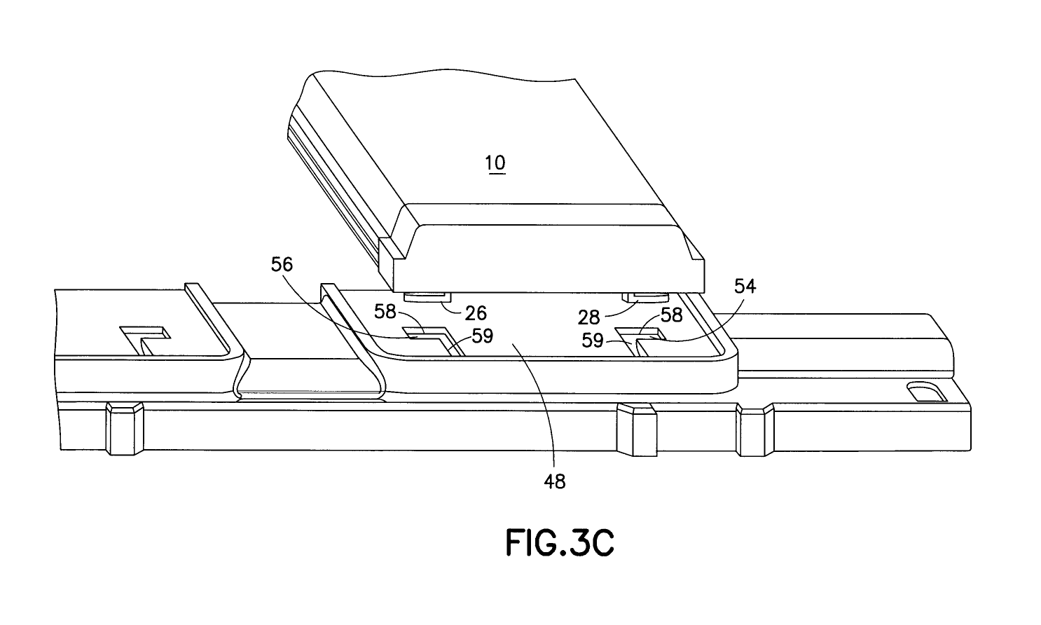

FIGS. 3A-3C illustrate an embodiment of the support strip 46 shown in FIGS. 2A-2B. In this embodiment, the support strip 46 includes three lamp holders 48, 50, and 52. The LED lamp 10 may be engaged with lamp holder 48 of the support strip 46 by inserting the feet 32 into respective apertures 54, 56 and sliding the LED lamp 10 in the direction of arrow A. The other end of LED lamp 10 is disposed on lamp holder 66, opposite the end supported by lamp holder 48. In combination, lamp holders 48 and 66 support a single LED lamp 10.

As shown in the perspective view of FIG. 3B, the lamp holders 48, 50, and 52 of the support strip 46 are illustrated in greater detail. Each lamp holder may include a left guide rail 68, a right guide rail 70, and/or a back guide rail 72. The guide rails are configured to help guide and direct the LED lamp 10 into engagement with the respective lamp holder.

FIG. 3C shows a perspective view of the lamp holder 48 with the LED lamp 10 in the process of being connected with the lamp holder 48. Tab 28 is configured to be inserted in rectangular portion 58 of aperture 54 and tab 26 is configured to be inserted in rectangular portion 58 of aperture 56.

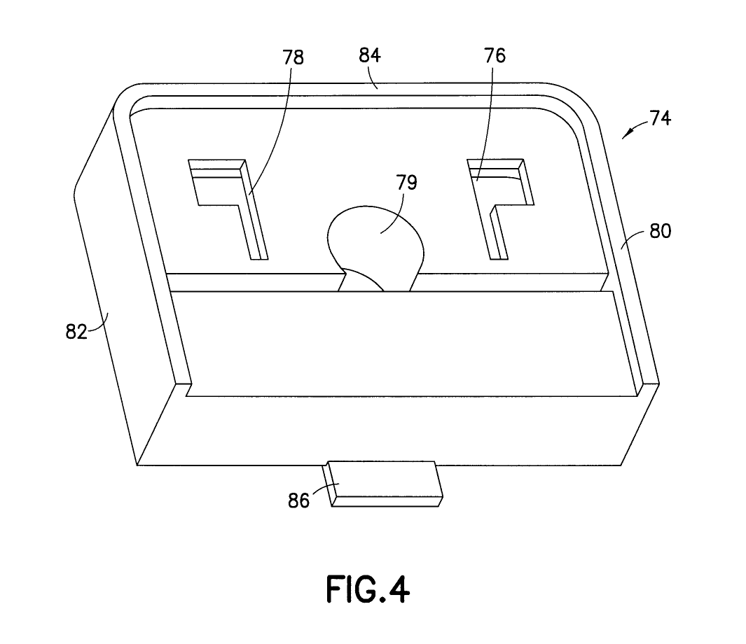

FIG. 4 illustrates another embodiment of a lamp holder 74. As shown, the lamp holder 74 includes a first aperture 76 and a second aperture 78. Lamp holder 74 may also include a first side guide rail 80, a second side guide rail 82, and a back guide rail 84. The lamp holder 74 may further include a circular aperture 79 as a means for securing the lamp holder 74 to a fixture or enclosure. Aperture 79 may be configured to receive a screw or similar type fastener to secure the lamp holder 74 to the fixture. A support tab 86 may also be included for allowing the lamp holder 74 to be installed on the light fixture. In this arrangement, the apertures 76 and 78 are configured such that an LED lamp may engage with the lamp holder 74 by sliding the LED lamp toward an opposite end. The engagement direction is reversed from the lamp holders shown in FIGS. 2 and 3 that enable engagement by sliding the LED lamp toward the same side. In some embodiments, the lamp holder 74 may be used on the opposite end from the lamp holders 48, 50, and 52 to allow sliding in the same direction (i.e., the direction indicated by arrow A in FIG. 3A). In this case, the lamp holder 74 may also include electrical contacts.

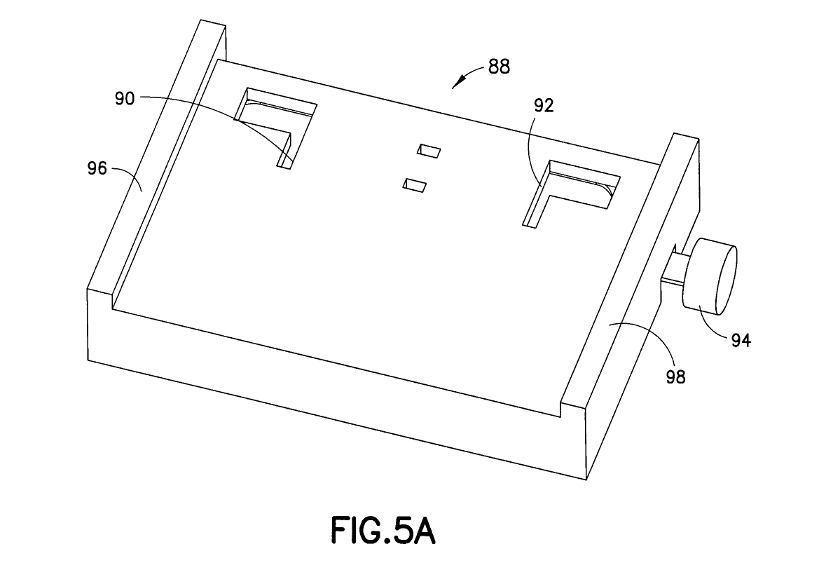

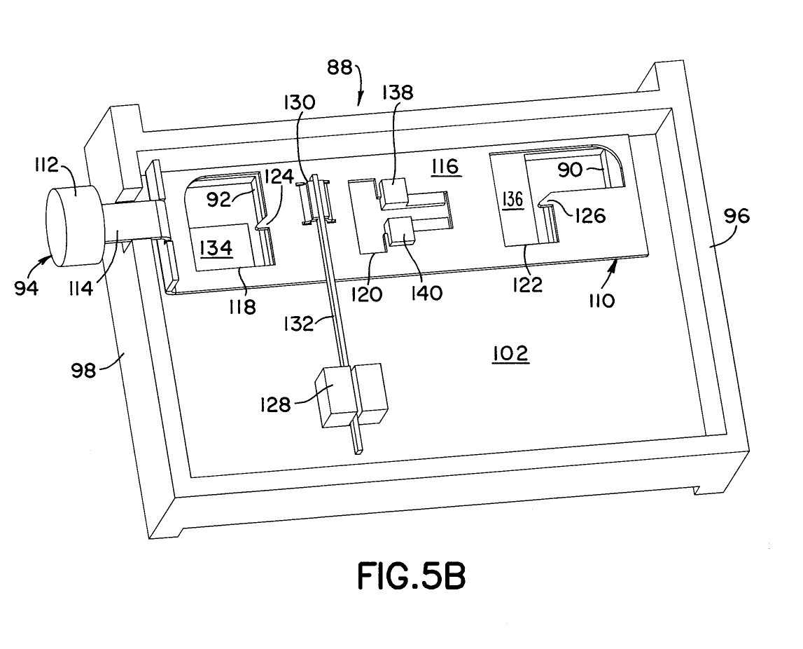

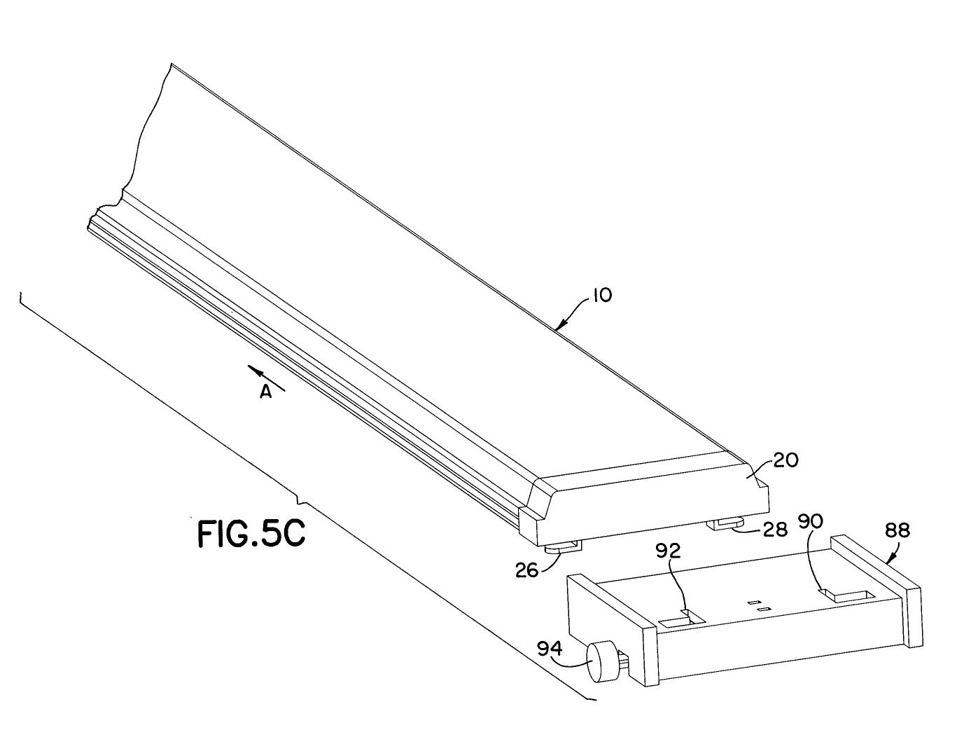

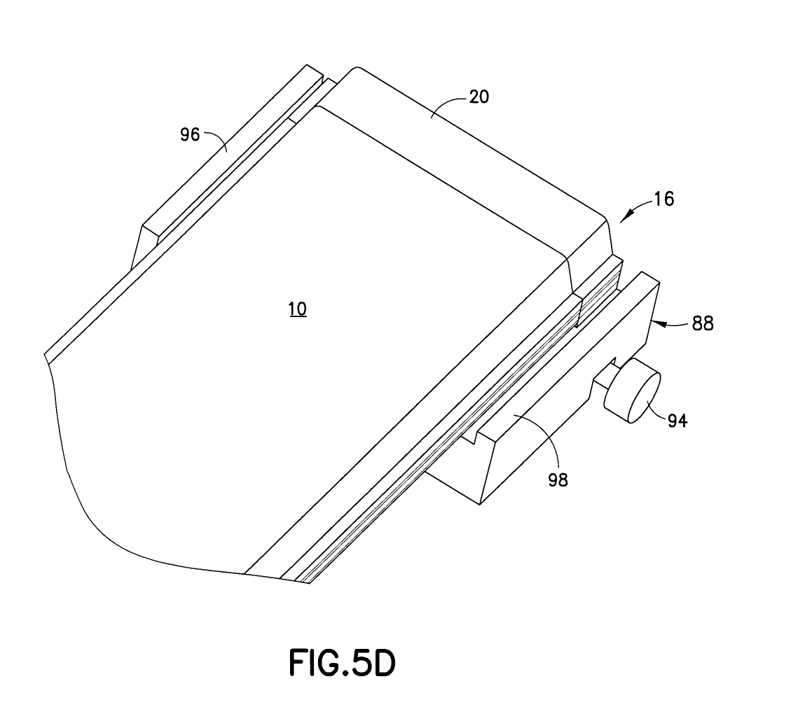

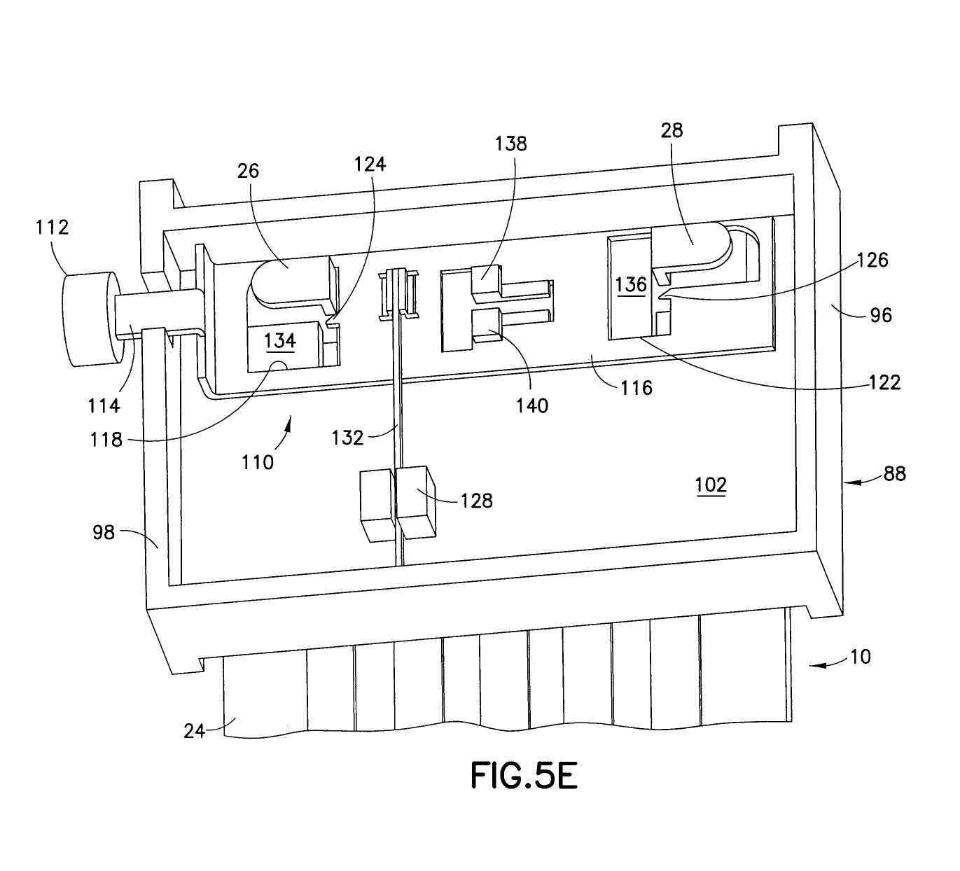

FIGS. 5A-5E show different views of another embodiment of a lamp holder 88. As illustrated in FIG. 5A, the lamp holder 88 includes a left aperture 90, a right aperture 92, a release button 94, left guide rail 96, and right guide rail 98. FIG. 5B is a perspective view showing an underside of the lamp holder 88. A bottom surface 102 includes the apertures 90 and 92. As shown, the lamp holder 88 includes a lock/release mechanism 110. The lock/release mechanism 110 may be moved laterally with respect to the bottom surface 102. The release button 94 includes a knob 112 connected to an arm 114. The arm 114 is attached to a plate 116 of the lock/release mechanism 110. When the release button 94 is pressed in a direction toward the right guide rail 98, the plate 116 is configured to slide toward the left guide rail 96.

The plate 116 includes a first aperture 118, a second aperture 120, and a third aperture 122. The plate 116 includes a first angled protrusion 124 and a second angled protrusion 126. The first and second angled protrusions 124 and 126 jut out into the first aperture 118 and third aperture 122, respectively.

The lock/release mechanism 110 further includes a first anchor 128 attached to the bottom surface 102 and a second anchor 130 attached to the plate 116. A spring 132 is supported between the anchors 128 and 130 and is configured to keep the plate 116 in a predetermined steady position with respect to the bottom surface 102. The spring 132 is configured to flex to allow the plate 116 to move with respect to the bottom surface 102 when the knob 112 is pressed. Attached to the bottom surface 102 are guide blocks 138 and 140, which have slits within which a portion of the plate 116 may slide. The guide blocks 138 and 140 allow the plate 116 to slide laterally.

FIGS. 5C-5E show views of the LED lamp 10 being connected to the lamp holder 88. The tabs 26 and 28 of LED lamp 10 are configured to be inserted in apertures 92 and 90, respectively. To securely engage the lamp holder 88, the LED lamp 10 may then be slid in the direction of arrow A. When the release button 94 is pressed, the LED lamp 10 is allowed to slide in the opposite direction of arrow A and the tabs 26 and 28 may be removed from the lamp holder 88.

FIG. 5E shows another view of the underside of the lamp holder 88 and the bottom surface 24 of the LED lamp 10. The foot of tab 26 is inserted through the aperture 118 of the plate 116. The foot may extend beyond the surface of the plate 116 or may be substantially aligned in the same plane of plate 116. When the LED lamp 10 is slid downward with respect to the page, the leg of tab 26 pushes against the angled portion of the protrusion 124 and the leg of tab 28 pushes against protrusion 126 (FIG. 5B). The force on the protrusions 124 and 126 causes the plate 116 to slide toward the left guide rail 96 until the legs go beyond the protrusions 124 and 126. Once the legs clear the protrusions 124 and 126, the spring 132 forces the plate 116 back in a direction toward the right guide rail 98 to lock the tabs 26 and 28 in place, thereby securing the LED lamp 10. To release the LED lamp 10, the knob 112 may be pressed, which moves the protrusions 124 and 126 out of the way, allowing the tabs 26 and 28 to slide beyond corner portions 134 and 136 of the bottom surface 102.

In other embodiments, the knob 112 and arm 114 are removed and a key receptacle may be provided and coupled to the plate 116. To release the LED lamp 10, a key, or similar instrument, may be inserted into the lamp holder 88 to engage the key receptacle moving plate 116 which moves the protrusions 124 and 126 out of the way, allowing the tabs 26 and 28 to slide beyond corner portions 134 and 136 of the bottom surface 102.

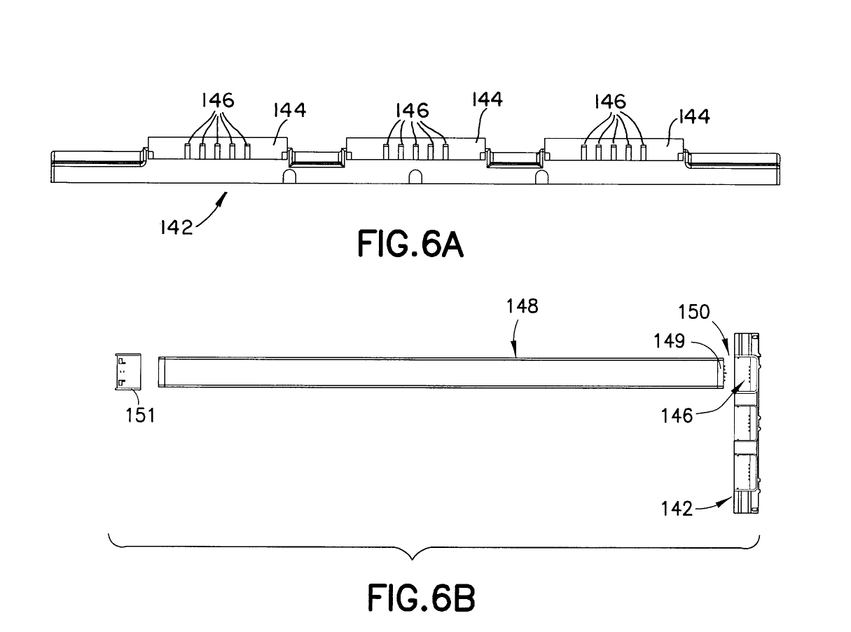

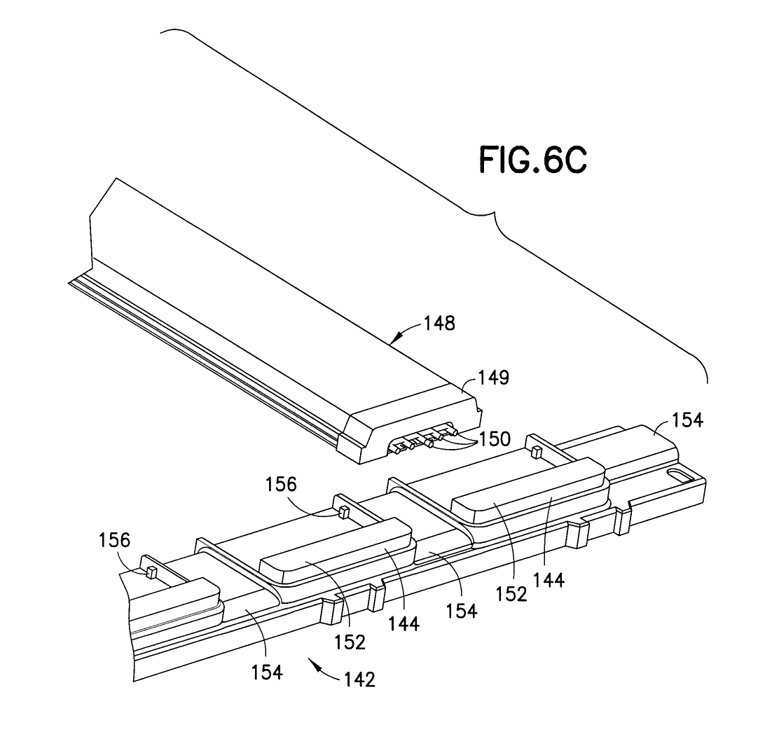

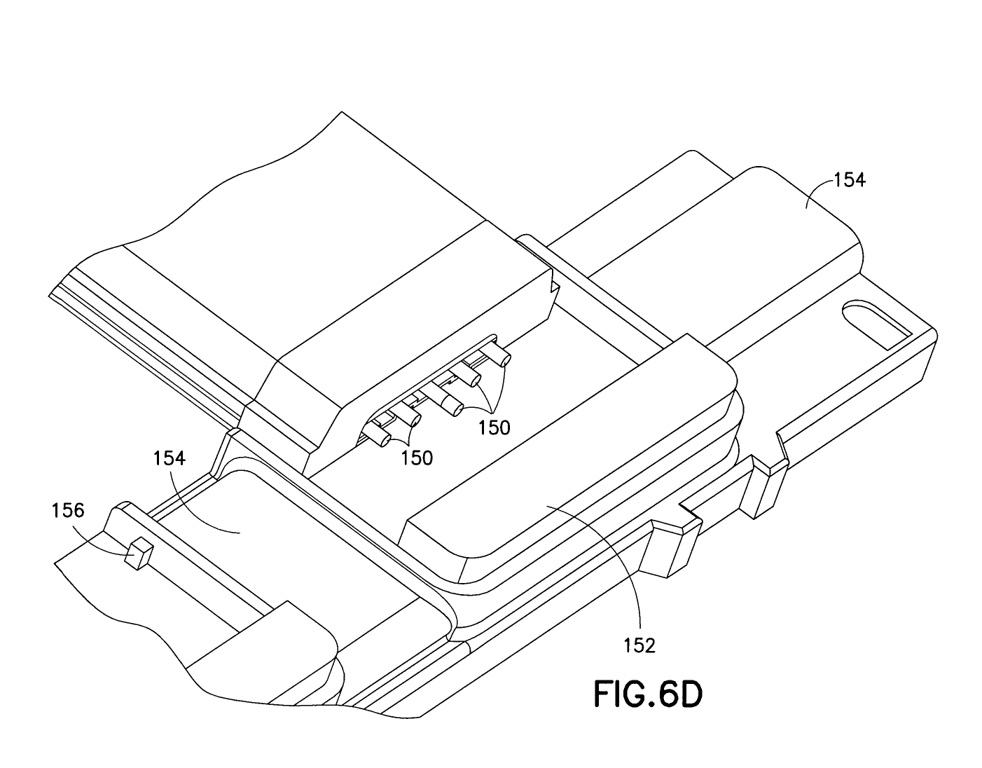

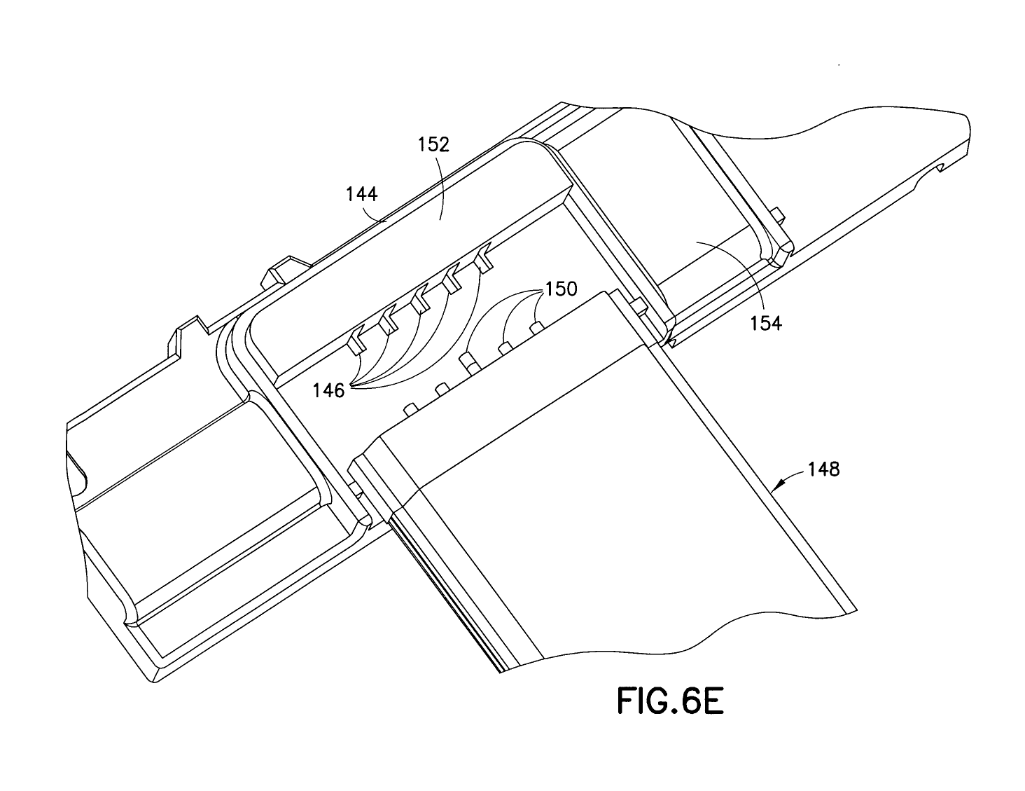

FIGS. 6A-6E illustrate different views of a first embodiment of a power supply strip 142. In this embodiment, the power supply strip 142 includes three receptacles 144. However, according to other implementations, the power supply strip 142 may contain any number of receptacles. Each receptacle 144 includes a plurality of recesses 146. One or more electrically conductive contacts are positioned inside the recess and are configured to provide electrical power and/or control signals to the LED lamp 10.

As shown in FIG. 6B, an LED lamp 148 is configured to be engaged with the power supply strip 142. The LED lamp 148 comprises an end cap 149 having a number of pins 150 that are configured to be inserted in the recesses 146. FIG. 6B also shows a lamp holder 151 that is configured to support the LED lamp 148 on its non-electrical end. FIGS. 6C-6E show that the receptacles 144 of the power supply strip 142 each comprise an overhang 152, which is configured to contain an opening have sufficient dimensions to enable the end cap 149 to be inserted under the overhang 152.

The power supply strip 142 further includes a driver 154 configured to carry electricity to the receptacles 144 for electrically driving the LED lamp 148. The power supply strip 142 also includes alignment blocks 156 configured to align the LED lamp 148 such that the pins 150 may be inserted in the recesses 146.

It is to be appreciated that although FIGS. 6A-6E show five pins 150 the illustration is only an example and the LED lamp 10 may have more or less than five pins depending on the functionality of the LED lamp 10. For example, in one embodiment, first and second electrically conductive pins or contacts are provided to provide power to the LED lamp, a third electrically conductive pin or contact provides a ground potential to the LED lamp, and fourth and fifth electrically conductive pins or contacts provide control signals to the LED lamp. In other embodiments, a ground pin or contact may not be provided and the third, fourth and fifth electrically conductive pins or contacts provide control signals to the LED lamp. The control signals may be provided to control color, color temperature, and brightness of light emitted from LED elements of the LED lamp.

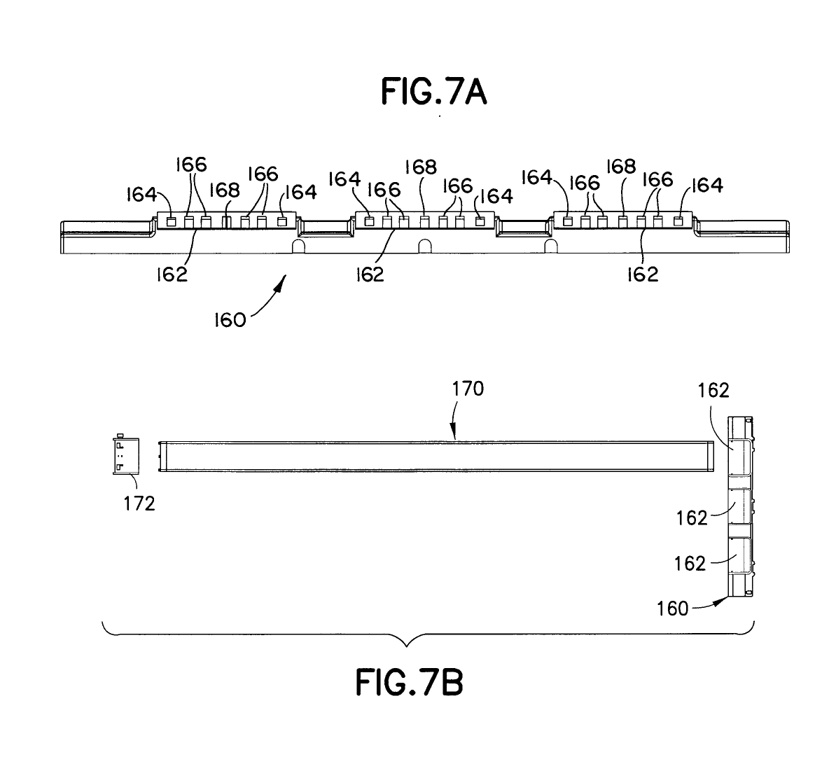

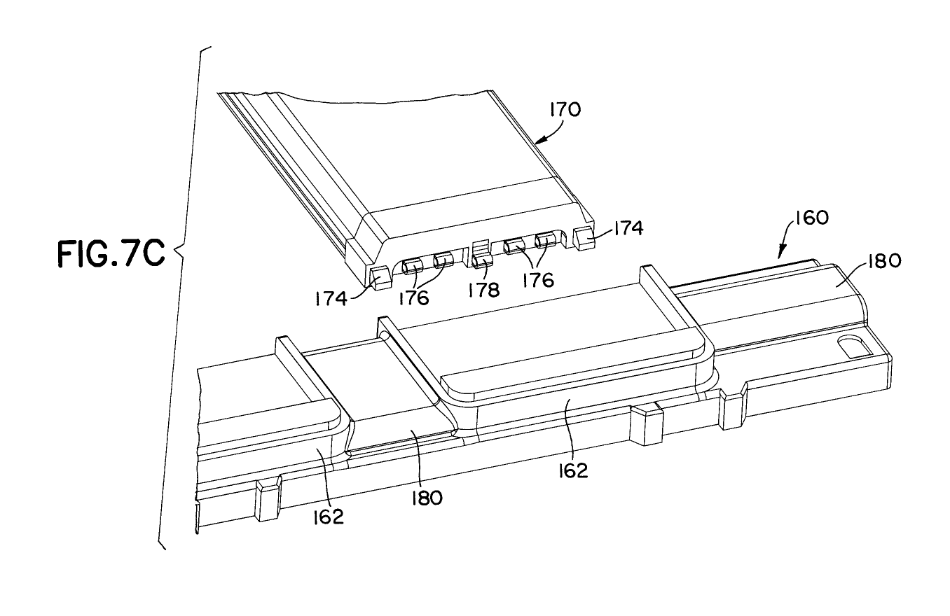

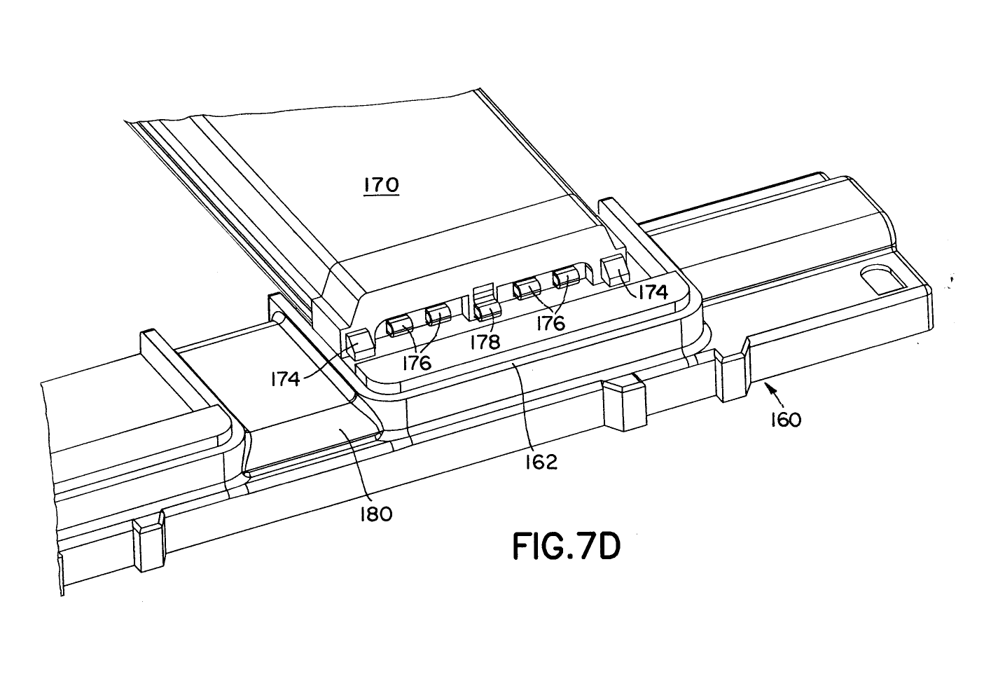

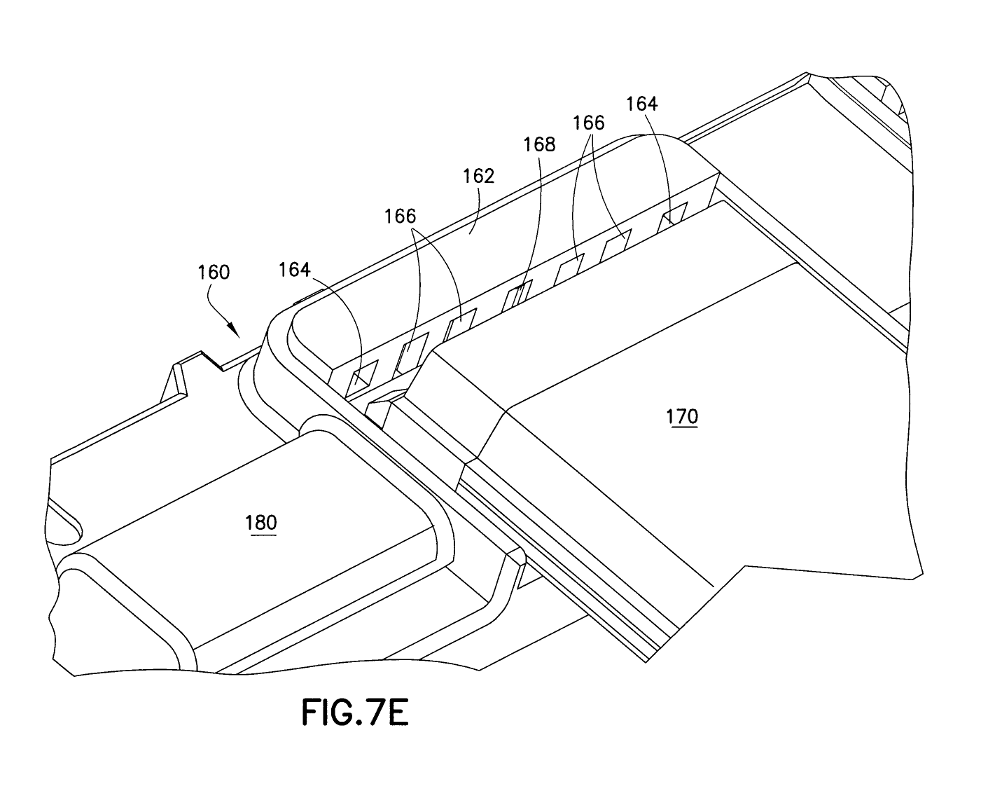

FIGS. 7A-7E illustrate different views of another embodiment of a power supply strip 160. As shown, the power supply strip 160 includes three receptacles 162, but may include any suitable number of receptacles according to various embodiments. Each receptacle 162 includes two support recesses 164, four contact recesses 166, and a control recess 168. The support recesses 164 are configured to receive projections on an LED lamp to support the weight of the LED lamp. The contact recesses 166 are configured to receive electrically conductive components (e.g., pins) protruding from the end of the LED lamp. Electrical contacts in the contact recesses 166 are configured to make electrical contact with the pins to provide power to the LED lamp. The control recess 168 is configured to receive a pin on the LED lamp and make electrical contact for providing control signals to the LED lamp.

FIG. 7B shows the power supply strip 160 with the three receptacles 162. Also shown is another embodiment of an LED lamp 170, which has one end that is configured to be supported by the power supply strip 160 and a second end that is configured to be supported by a non-electrical lamp holder 172.

As illustrated in FIG. 7C, the power supply strip 160 further includes a drive circuit 180 configured to provide power to the receptacles 162, which in turn provide power to the LED lamps. The LED lamp 170 has an end cap that comprises a pair of support pegs 174. The LED lamp 170 also includes four spring pins 176 and a control pin 178. The spring pins 176 and control pin 178 may each contain a rounded ribbon of electrically conductive material for making electrical contact while providing a small amount of compression to the contacts of the receptacle 162. FIGS. 7D and 7E show that the support pegs 174 are aligned with and inserted in the support recesses 164. In some embodiments, the receptacles 162 may further comprise an overhang for providing additional support for the end of the LED lamp 170.

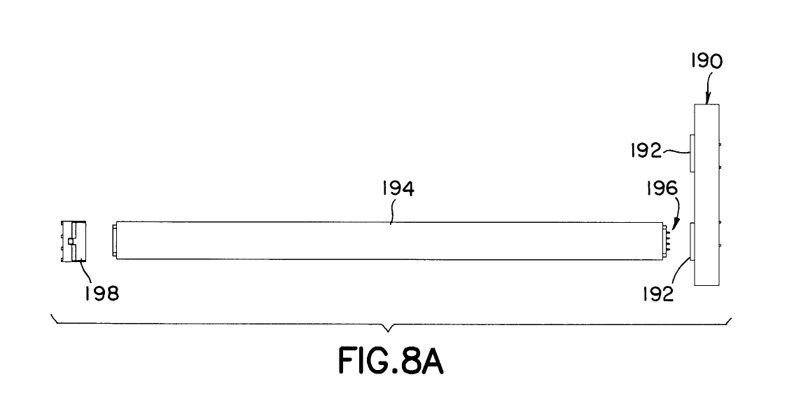

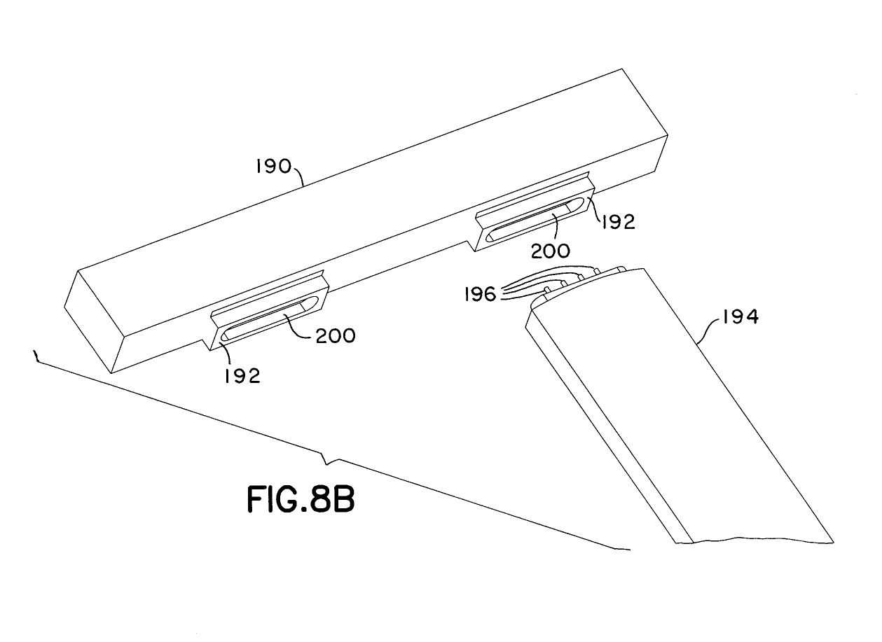

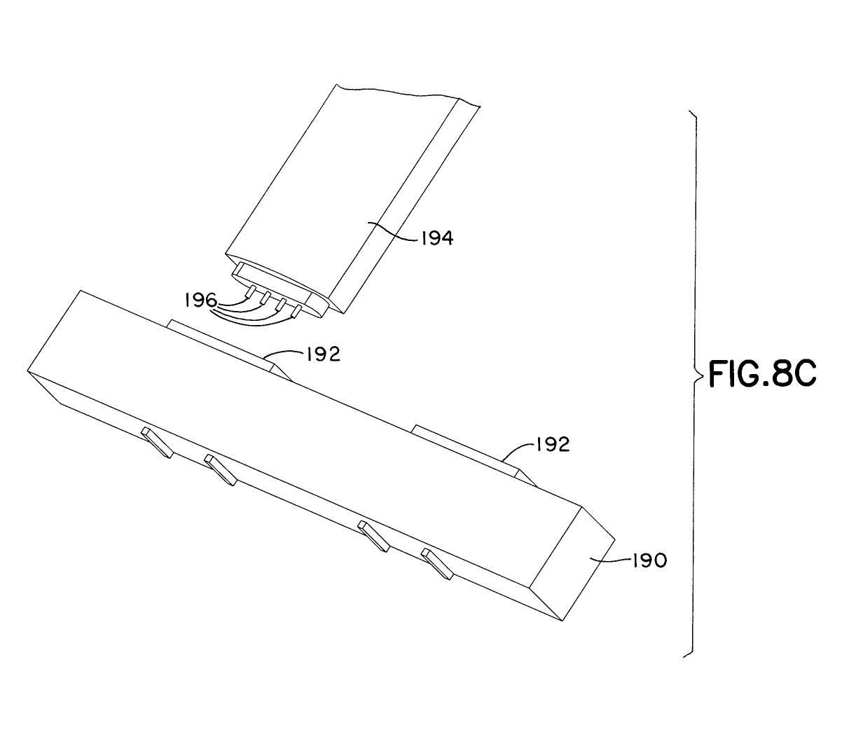

FIGS. 8A-8C are views showing another embodiment of a power supply strip 190. As shown in this embodiment, the power supply strip 190 comprises two fixed receptacles 192, but any number of receptacles may be included according to various implementations. Another embodiment of a corresponding LED lamp 194 is shown in FIGS. 8A-C. The LED lamp 194 includes a number of pins 196 that are inserted in one of the receptacles 192. At the other end of the LED lamp 194, an embodiment of a non-electrical lamp holder 198 is shown. The lamp holder 198 is configured to support the non-electrical end of the LED lamp 194. The receptacles 192 each comprise a recess 200 that accommodate the end portion of the LED lamp 194. Power supply strip 190 includes drive circuitry for providing power to the LED lamps 194 via electrical contacts residing in the recesses 200 when the pins 196 are coupled to the electrical contacts.

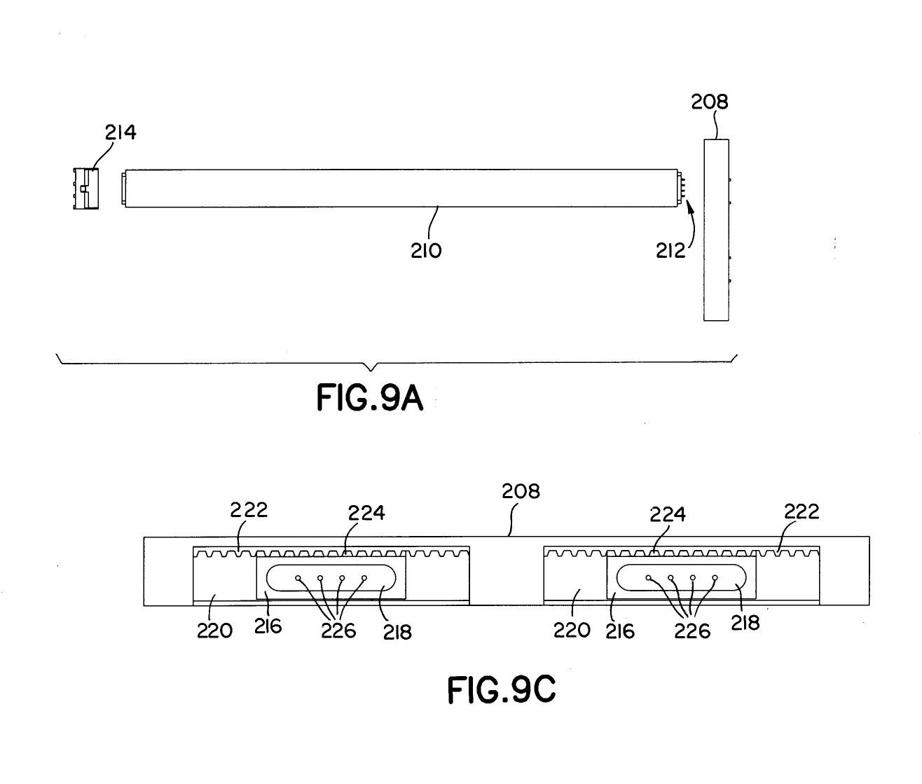

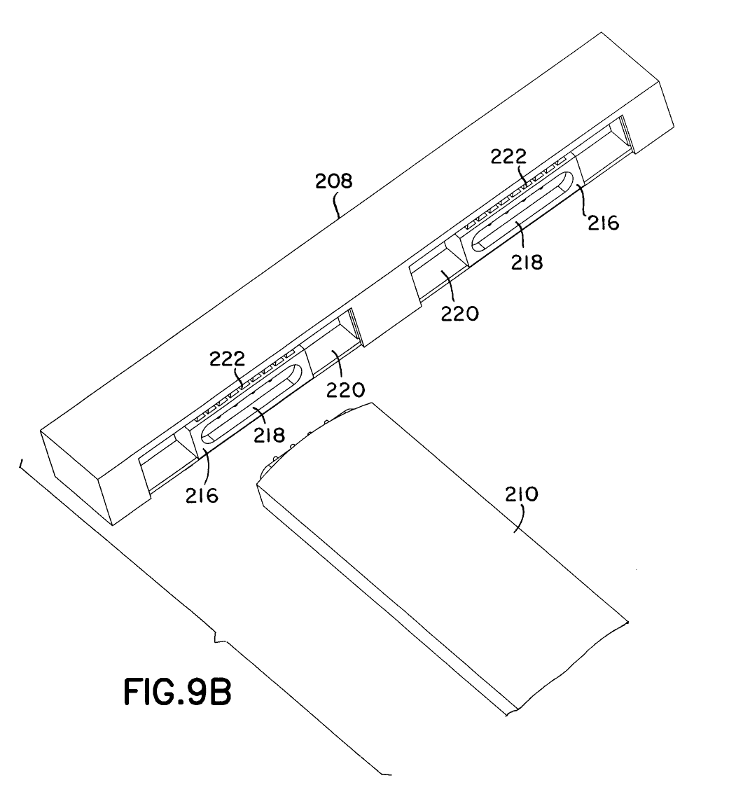

FIGS. 9A-9C are views of another embodiment of a power supply strip 208. As shown, the power supply strip 208 is configured to support and provide power to another embodiment of an LED lamp 210. The LED lamp 210 comprises pins 212 at one end and physical features at the other end to enable the LED lamp 210 to be supported by a lamp holder 214. FIG. 9B shows a perspective view of the power supply strip 208. As illustrated, the power supply strip 208 further includes a number of receptacles 216 configured to support and provide power to the electrical end of the LED lamp 210.

The receptacles each comprise a slot 218 configured to accommodate an end portion of the LED lamp 210. Each receptacle 216 is configured to be moveable from side to side within an opening 220 in the power supply strip 208 to allow an installer to position the LED lamp 210 in any desired position along the width of the opening 220. A top edge of the opening 220 contains a set of teeth 222 that are configured to be engaged with corresponding teeth 224 on the receptacle 216. When the receptacle 216 is positioned in a desired location in the opening 220, teeth 222 and 224 may be locked to keep the receptacle 216 secured. As shown in FIG. 9C, contacts 226 are positioned within the slot 218 and are configured to be in electrical contact with the pins 212 when the end of the LED lamp 210 is properly inserted in the slot 218.

In one embodiment, a conducting rail or power bus may be provided in opening 220 so as to provide power to receptacle 216 regardless of its final position along opening 220. Receptacle 216 will be configured to maintain contact with the rail or bus as its is moved within opening 220.

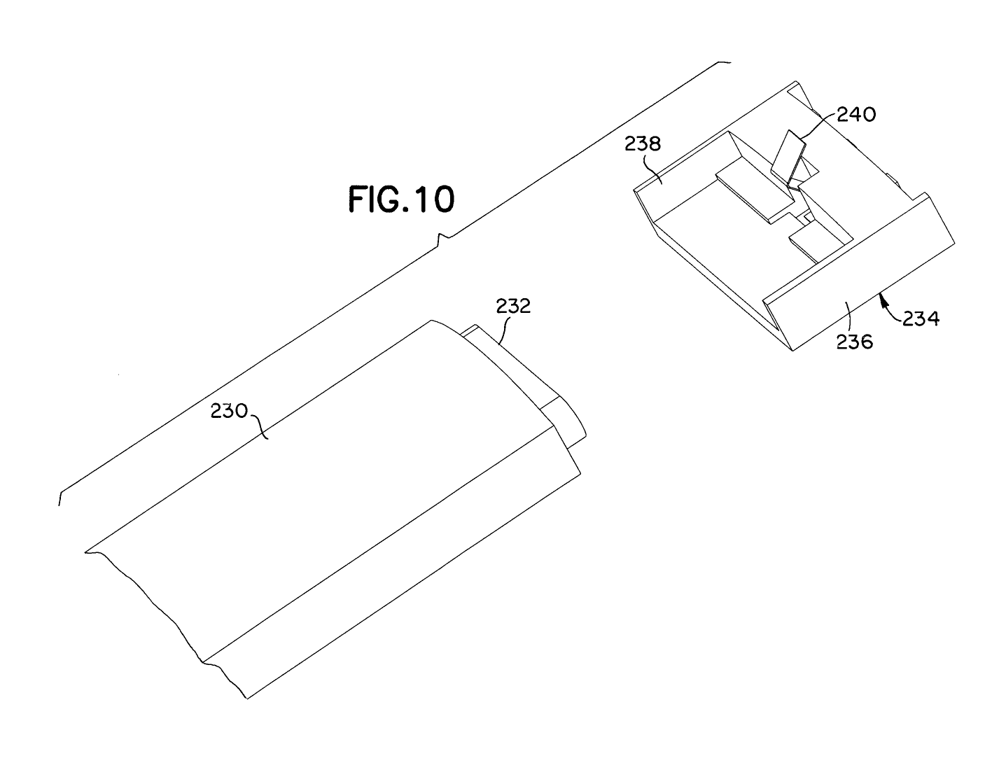

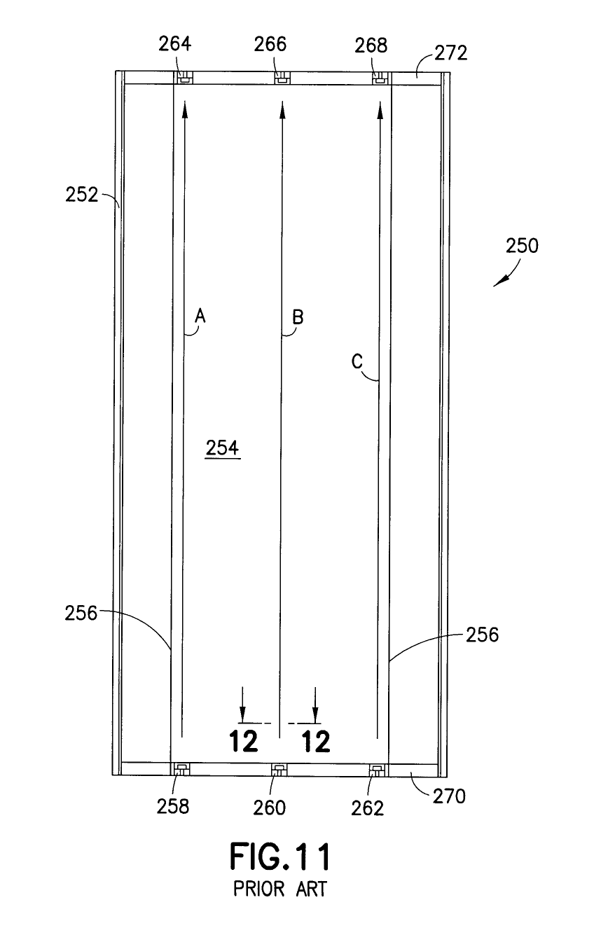

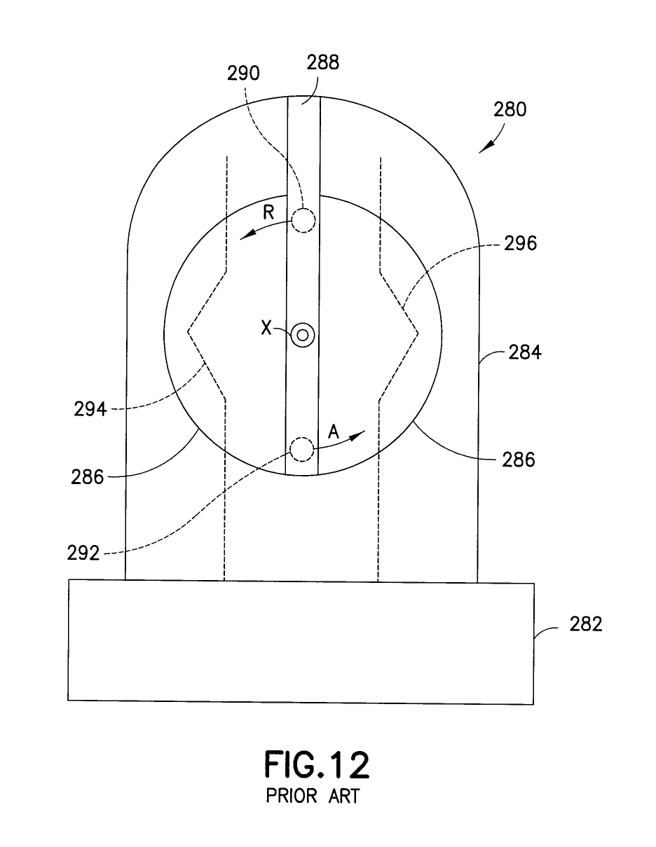

FIG. 10 is a perspective view of another embodiment of an LED lamp 230 having a support element 232. The support element 232 may be configured on the non-electrical end of the LED lamp 230 to enable physical support for the LED lamp 230 at that end. A lamp holder 234, according to another embodiment, is configured to receive the support element 232 and physically support the weight of the end of the LED lamp 230. The lamp holder 234 includes a right guide rail 236 and a left guide rail 238. The lamp holder 234 further includes a latch 240 configured to lock the LED lamp 230 in place. The latch 240 may be moved or flexed to allow the support element 232 to be removed from the lamp holder 234.

It is to be appreciated that the various features shown and described are interchangeable, that is a feature shown in one embodiment may be incorporated into another embodiment.

The various implementations described herein are not intended to limit the present disclosure, but may include additional features and advantages not necessarily expressed herein. The additional features and advantages may be apparent to one of ordinary skill in the art upon examination of the detailed description and accompanying drawings, according to spirit and scope of the present disclosure. It is intended that all such additional features and advantages be included within the present disclosure and protected by the accompanying claims.

I/We claim:

1. A light emitting diode (LED) light fixture comprising:
a housing having a back surface, a first end portion, and a second end portion;
a support strip attached to the back surface of the housing adjacent to the first end portion, the support strip having at least one lamp holder configured to physically support a first end of at least one LED lamp; and
a power supply strip attached to the back surface of the housing adjacent to the second end portion, the power supply strip having at least one receptacle configured to physically support a second end of the at least one LED lamp, the at least one receptacle further configured to provide electrical power to the at least one LED lamp.

2. The LED light fixture of claim 1, wherein the support strip comprises a plurality of lamp holders, the plurality of lamp holders configured to physically support first ends of a plurality of LED lamps, and wherein the power supply strip comprises a plurality of receptacles, the plurality of receptacles configured to physically support second ends of the plurality of LED lamps, the plurality of receptacles further configured to provide electrical power to the plurality of LED lamps.

3. The LED light fixture of claim 1, wherein the at least one lamp holder comprises a first aperture and a second aperture.

4. The LED light fixture of claim 3, wherein the at least one LED lamp comprises:
a body having a top surface, bottom surface, first end, and second end;
a plurality of LED elements configured to emit light when power is applied to the LED lamp;
a first end cap connected to the first end; and
a second end cap connected to the second end;
wherein the first end cap includes a first tab and a second tab, the first and second tabs each including a leg protruding from a bottom surface of the first end cap and a foot directed away from the other respective tab.

5. The LED light fixture of claim 4, wherein the first and second apertures are configured to receive the first and second tabs of the at least one LED lamp.

6. The LED light fixture of claim 1, wherein the at least one lamp holder comprises a first aperture and a second aperture, each of the first and second apertures including an opening and a slit, the opening configured to accommodate a respective tab of the LED lamp, the slit configured to enable the respective tab to be slid into an engagement position.

7. The LED light fixture of claim 6, wherein the at least one lamp holder further comprises a locking mechanism to prevent the at least one LED lamp from being removed from the at least one lamp holder.

8. The LED light fixture of claim 7, wherein the at least one lamp holder further comprises a spring element configured to keep the locking mechanism in a locking position.

9. The LED light fixture of claim 7, wherein the at least one lamp holder further comprises a release knob connected to the locking mechanism, the release knob configured to allow the locking mechanism to release the at least one LED lamp.

10. The LED light fixture of claim 1, wherein the at least one receptacle comprises a plurality of recesses configured to receive electrical components of the at least one LED lamp.

11. The LED light fixture of claim 10, wherein the at least one receptacle further comprises at least one electrically conductive contact located in each of the plurality of recesses, the electrically conductive contacts configured to electrically communicate with corresponding electrical components of the at least one LED lamp.

12. The LED light fixture of claim 11, wherein first and second electrically conductive contacts provide power to the at least one LED lamp.

13. The LED light fixture of claim 12, further comprising at least one additional electrically conductive contact configured to control at least one of color, color temperature, or brightness of light emitted from LED elements of the at least one LED lamp.

14. The LED light fixture of claim 10, wherein the electrical components of the at least one LED lamp are pins protruding from the second end of the LED lamp.

15. The LED light fixture of claim 10, wherein the electrical components of the at least one LED lamp are curved metal ribbons protruding from the second end of the at least one LED lamp.

16. The LED light fixture of claim 1, wherein the at least one receptacle further comprises an overhang configured to physically support the at least one LED lamp.

17. The LED light fixture of claim 1, wherein the at least one receptacle further comprises at least one support recess, each support recess configured to receive a support block protruding from the second end of the at least one LED lamp.

18. The LED light fixture of claim 1, wherein the at least one receptacle is laterally movable within an aperture of the power supply strip.

19. The LED light fixture of claim 18, wherein the aperture of the power supply strip comprises a locking device to lock the at least one receptacle in place.

20. The LED light fixture of claim 1, wherein a top surface and bottom surface of the at least one LED lamp are substantially flat.

21. The LED light fixture of claim 1, wherein the at least one lamp holder comprises at least one guide rail configured to direct the first end of the at least one LED lamp into engagement with the at least one lamp holder.

22. A power supply strip of a light emitting diode (LED) light fixture, the power supply strip comprising:
at least one receptacle configured to engage an electrical end of at least one LED lamp; and
a drive circuit configured to provide electrical power to the at least one LED lamp through the at least one receptacle;
wherein each of the at least one receptacle includes electrical contacts configured to supply the electrical power from the drive circuit to the electrical end of the at least one LED lamp.

23. The power supply strip of claim 22, wherein each of the at least one receptacle comprises one or more electrical contacts positioned within each of a plurality of recesses, the electrical contacts configured to provide power and control signals to the electrical end of the at least one LED lamp.

24. The power supply strip of claim 22, wherein the at least one LED lamp comprises a non-electrical end opposite from the electrical end.

25. The power supply strip of claim 22, wherein the at least one receptacle is laterally movable within an aperture of the power supply strip.

26. The power supply strip of claim 25, wherein the aperture of the power supply strip comprises a locking device to lock the at least one lamp holder in place.

27. A method of manufacturing a light emitting diode (LED) light fixture, the method comprising:
providing a fluorescent light fixture having a first end and a second end, each of the first and second ends comprising one or more fluorescent tube lamp holders and a ballast;
removing the fluorescent tube lamp holders and ballasts;
mounting a support strip at the first end of the fluorescent light fixture, the support strip comprising at least one lamp holder configured to support a first end of at least one LED lamp; and
mounting a power supply strip at the second end of the fluorescent light fixture, the power supply strip configured to support a second end of the at least one LED lamp and provide power to the at least one LED lamp.

28. The method of claim 27, further comprising incorporating an electrical driver in the power supply strip, the electrical driver configured to drive LED elements of the at least one LED lamp.

29. The method of claim 27, further comprising configuring the support strip and power supply strip to prohibit connection with a standard fluorescent lamp.
